(19) United States
(12) Patent Application Publication
(10) Pub. No.: US 2009/0108353 A1
(43) Pub. Date: Apr. 30, 2009

(54) FINFET STRUCTURE AND METHODS

(75) Inventor: Hyun-Jin CHO, Palo Alto, CA (US)

Correspondence Address: INGRASSIA FISHER & LORENZ, P.C. (AMD), 7010 E. COCHISE ROAD, SCOTTSDALE, AZ, 85253, US

(73) Assignee: ADVANCED MICRO DEVICES, INC., Austin, TX (US)

(21) Appl. No.: 11/932,136

(22) Filed: Oct. 31, 2007

(51) Int. Cl. H01L 27/12; H01L 21/84

(52) U.S. Cl. 257/347; 438/157; 257/E27.112; 257/E21.703

(57) ABSTRACT

A FinFET structure is fabricated by patterning a semiconductor substrate to form a nonplanar semiconductor structure including a first fin, a second fin substantially parallel to the first fin, and an inter-fin semiconductor strip coupled therebetween. The first fin, the second fin, and the inter-fin semiconductor strip each extend from a drain region to a source region. A gate dielectric layer is formed on the first and second fins and the inter-fin semiconductor strip in a gate region substantially orthogonal to the first and second fins and between the drain and source region. A gate electrode layer is formed on the gate dielectric layer. The semiconductor substrate may be a silicon-on-insulator (SOI) material comprising a buried oxide layer (BOX) having a silicon layer formed thereon.

### FIELD OF THE INVENTION

The present invention generally relates to MOS structures and methods for fabricating MOS structures, and more particularly relates to nonplanar, multi-gate MOSFET structures known as FinFETs.

### BACKGROUND OF THE INVENTION

In contrast to traditional planar metal-oxide-semiconductor field-effect transistors (MOSFETs), which are fabricated using conventional lithographic fabrication methods, nonplanar FETs incorporate various vertical transistor structures, and typically include two or more gate structures formed in parallel. One such semiconductor structure is the “FinFET,” which takes its name from the multiple thin silicon “fins” that are used to form the respective gate channels, and which are typically on the order of tens of nanometers in width. In general, the FinFET is one of a class of nonplanar, multi-gate transistors typically built on a silicon-on-insulator (SOI) substrate.

More particularly, referring to the exemplary prior art nonplanar FET structure shown in FIG. 1, a FinFET 100 generally includes two or more parallel silicon fin structures (or simply “fins”) 104 and 106. As mentioned previously, these structures are typically formed on a SOI substrate (not shown), and may include three, four, or even more parallel fins. Fins 104 and 106 extend between a common drain electrode and a common source electrode (not shown). A conductive gate structure 102 “wraps around” three sides of both fins 104 and 106, and is separated from the fins by a standard gate oxide layer 103. Fins 104 and 106 may be suitably doped to produce the desired FET polarity, as is known in the art, such that the gate channel is formed within the near surface of the fins adjacent to gate oxide 103. The dimensions of the fin thus determine the effective channel length of the device.

As conventional MOSFET gate lengths are scaled below 100 nm, the resulting FET may be subject to excessive leakage and other short-channel effects. FinFETs, by virtue of their non-planar gate channel structure, do not exhibit these short-channel effects. Nevertheless, while FinFETs are advantageous with respect to scalability and electrical characteristics, there is a continuing need to improve their performance. For example, it is desirable to provide FinFET structures that can accommodate increased drive current (i.e., the drain-source current that can flow through the parallel fins). Furthermore, it is desirable to reduce the effective contact resistance of the structure. These and other desirable features and characteristics of the present invention will become apparent from the subsequent detailed description of the invention and the appended claims, taken in conjunction with the accompanying drawings and this background of the invention.

### BRIEF SUMMARY OF THE INVENTION

FinFET structures and methods are provided. In one embodiment, a fabrication method includes patterning a semiconductor substrate to form a nonplanar semiconductor structure comprising a first fin, a second fin substantially parallel to the first fin, and an inter-fin semiconductor strip coupled therebetween. The first fin, the second fin, and the inter-fin semiconductor strip each extend from a drain region to a source region. A gate dielectric layer is formed on the first and second fins and the inter-fin semiconductor strip in a gate region substantially orthogonal to the first and second fins and between the drain and source region. A gate electrode layer is then formed on the gate dielectric layer. In one embodiment, the semiconductor substrate is a silicon-on-insulator (SOI) material comprising a buried oxide layer (BOX) having a silicon layer formed thereon.

### BRIEF DESCRIPTION OF THE DRAWINGS

The present invention will hereinafter be described in conjunction with the following drawing figures, wherein like numerals denote like elements, and wherein:

FIG. 1 is an isometric conceptual overview of a traditional prior art FinFET structure;

FIG. 2 is an isometric conceptual overview of a FinFET structure in accordance with various embodiments of the present invention; and

FIGS. 3-10 illustrate, in cross section, a method for fabricating a FinFET structure in accordance with an exemplary embodiment of the present invention.

### DETAILED DESCRIPTION OF THE INVENTION

In general, the present invention relates to a fin field-effect transistor (“FinFET”) structure that incorporates a thin, inter-fin semiconductor strip between two or more parallel, non-planar fin structures, thereby increasing drive current and reducing effective contact resistance. In this regard, the following detailed description is merely exemplary in nature and is not intended to limit the range of possible embodiments and applications. Furthermore, there is no intention to be bound by any theory presented in the preceding background or the following detailed description.

For simplicity and clarity of illustration, the drawing figures depict the general structure and/or manner of construction of the various FinFET embodiments. Elements in the drawings figures are not necessarily drawn to scale: the dimensions of some features may be exaggerated relative to other elements to assist improve understanding of the example embodiments.

Terms of enumeration such as “first,” “second,” and the like may be used for distinguishing between similar elements and not necessarily for describing a particular spatial or chronological order. These terms, so used, are interchangeable under appropriate circumstances. The embodiments of the invention described herein are, for example, capable of use in sequences other than those illustrated or otherwise described herein. Unless expressly stated otherwise, “connected” means that one element/node/feature is directly joined to (or directly communicates with) another element/node/feature, and not necessarily mechanically. The terms “comprise,” “include,” “have” and any variations thereof are used synonymously to denote non-exclusive inclusion. The term “exemplary” is used in the sense of “example,” rather than “ideal.”

In the interest of conciseness, conventional techniques, structures, and principles known by those skilled in the art may not be described herein, including, for example, standard semiconductor processing techniques, fundamental principles of semiconductor devices, and basic operational principles of FETs. For the purposes of clarity, some commonly-used layers may not be illustrated in the drawings, including various protective cap layers, seed layers, substrates, or the like.

Referring now to the conceptual isometric overview depicted in FIG. 2, a Fin Field Effect Transistor (“FinFET”) structure 200 in accordance with one embodiment of the present invention generally includes two or more substantially parallel semiconductor fin structures (or simply “fins”) 104, 106, and an inter-fin strip of semiconductor material 202 formed therebetween. Each of the fins 104 and 106, as well as inter-fin strip (or simply “strip”) 202, extend from a common drain contact to a common source contact (not shown), thus providing a path for conducted drain-source current. The fins 104, 106 are doped to produce respective drain and source regions as shown. Note that FIG. 2 is not necessarily to scale, and that the illustrated aspect ratios—as well as the number of illustrated fins—are not intended as limitations. Furthermore, the term “fin” is used to refer to any nonplanar structure whose length and height (using the designations described with respect to FIG. 2) are greater than its width. The fin need not be strictly uniform, symmetrical, or rectilinear in cross section, and indeed may have any suitable curvilinear shape. The method may also include forming a plurality of fins parallel to the first fin, such that a total of N fins are fabricated, then forming a plurality of inter-fin semiconductor strips between each pair of fins n and n+1 for n=1 to N−1, inclusive.

Inter-fin strip 202 is preferably contiguous with (i.e., electrically and physically connected to) both fins 104 and 106, and has a doping profile along its length (i.e., along the y-axis) that is equivalent to that of fins 104 and 106. That is, various portions of fins 104, 106, and 202, may be doped with P-type conductivity-determining impurities or N-type conductivity-determining impurities using, for example, implantation and subsequent thermal annealing of dopant ions such as boron or arsenic. The selection of dopant species depends upon, inter alia, the desired polarity and type of FET structure, as is known in the art.

In accordance with one embodiment, and as described in further detail below, fins 104 and 106 are non-planar structures formed using a SOI substrate—i.e., by selectively patterning the silicon layer to form fins that extend in the z direction from the underlying buried oxide layer 204 such that an inter-fin strip 202 remains.

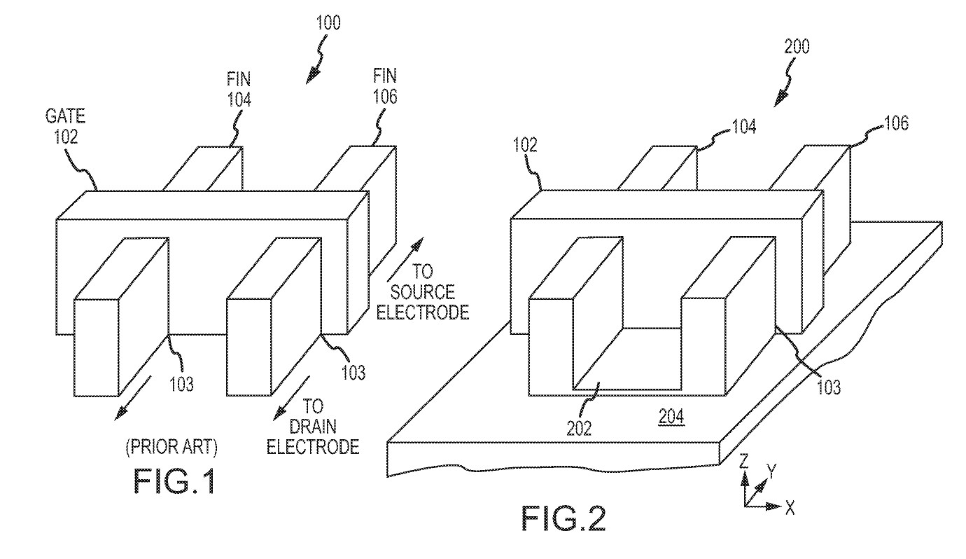

A conductive gate structure 102 (e.g., a polysilicon or metal gate) “wraps around” three sides of both fins 104 and 106 and overlies strip 202 in a gate region orthogonal to the fins, and is separated from the fins by a suitable gate dielectric layer 103 (e.g., a conventional oxide layer). Fins 104 and 106 are doped to produce the desired FET polarity, as is known in the art, such that the gate channel is formed within the near surface of the fins adjacent to gate oxide 103. The dimensions of the fin (i.e., its height along the z-axis, its width along the x-axis) as well as the width along the x-axis of the inter-fin strip 202 together determine the effective channel width of the FET device. Comparing the illustrated embodiment of FIG. 2 with the prior art structure of FIG. 1, it can be seen that the additional inter-fin strip 202 provides additional cross-sectional area through which the drain-source current flows, and thereby increases the total channel width.

The various dimensions of fins 104, 106, and inter-fin strip 202 may be selected to achieve particular device performance. In one embodiment, for example, the gate length as determined by the length in y direction of gate 102 is on the order of 10-100 nm, and the thickness of inter-fin strip 202 is between approximately 5-20 nm. The fins preferably have a height of about 10-100 nm, a width of about 10-100 nm, and a length that is significantly greater than 10 nm. In various embodiments inter-fin semiconductor strip has a first thickness that is less than the fin height by approximately a factor of 2 to 5.

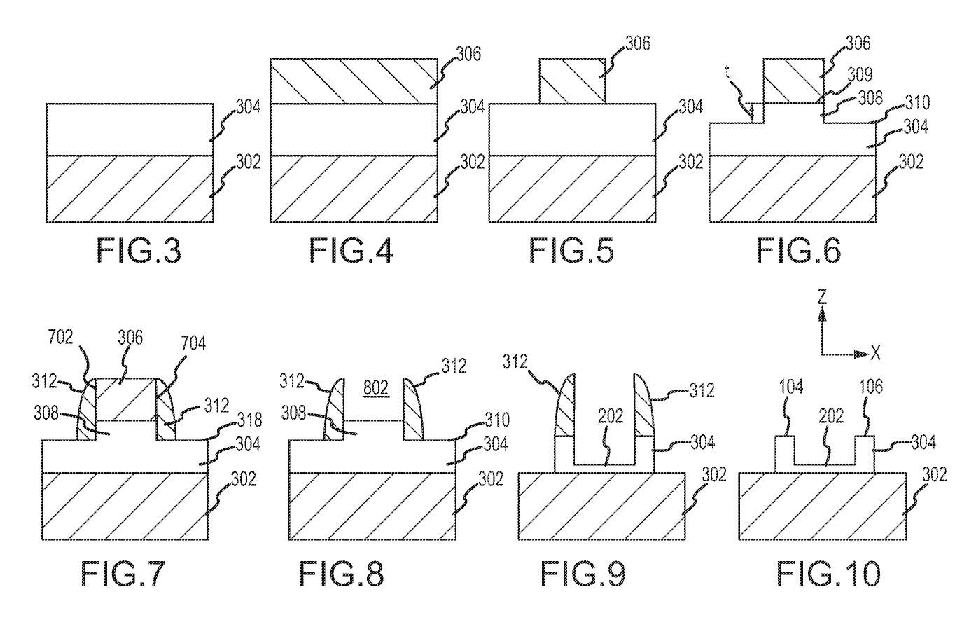

Having thus given an overview of an exemplary FinFET structure 200, a method of fabricating such a structure will now be described in conjunction with FIGS. 3-10. This sequential series of figures illustrate, in cross section, a method for forming a FinFET in accordance with one embodiment of the present invention.

Initially, a silicon-on-insulator (SOI) substrate 304 is provided, including a silicon layer 304 and a buried oxide layer 302. Buried oxide layer 302 is typically incorporated into a further structural silicon layer, which for clarity is not shown in the figures. A variety of methods may be used to produce such an SOI substrate, including, for example, SIMOX (Separation by IMplantation of OXygen), wafer bonding, and various seed methods. Note that while the illustrated invention is described in the context of a silicon substrate, other semiconductor materials or combinations thereof may be used, including Ge, Si—Ge, and the like.

Next, as depicted in FIG. 4, a blanket dielectric layer 306 (e.g., a silicon dioxide layer) is formed over silicon layer 304. This layer may, for example, have a thickness of between approximately 500 and 5000 nm. Dielectric layer 306 is subsequently patterned (using, for example, standard photolithography processes) to create elongated oxide structures (or “caps”) 306 that will ultimately define the distance between adjacent fins (FIG. 5).

Next, as shown in FIG. 6, silicon layer 304 is etched such that a portion of the layer is masked by cap structure 306, thus forming a “shoulder” profile that results in a thicker region 308 of silicon below cap structure 306. Region 308 has a thickness t with respect to the resulting surface 310 of silicon layer 304. In one embodiment, layer 304 is etched such that t is approximately 100 nm.

As shown in FIG. 7, sidewall structures 312 are formed extending from surface 310 of silicon layer 304 and along the sides 702 and 704 of dielectric structure 306 and silicon region 308. These sidewall structures may consist, for example, of silicon nitride, silicon oxy-nitride, or the like, and may be fabricated using standard deposition and anisotropic etching techniques.

Next, the dielectric layer 306 is etched away to leave an opening 802 bordered by layer 304 and sidewall spacers 312. This etching process may be performed using a selected wet or dry etch technique.

Next, the silicon layer 304 is selectively etched such that the thinner, outer regions (defined by surface 310) are substantially etched away to leave fins 104, 106, and the central region underlying area 802 (formerly region 308) between spacers 312 is partially etched away such that the aforementioned thin inter-fin strip 202 remains. The thickness of inter-fin strip 202 is determined by, among other things, the difference in thicknesses of silicon layer 304 between spacers 312 and external to spacers 312, as well as the etching process used. The etch process is chosen such that the silicon layer 304 as well as central region 308 are etched uniformly while the spacer layer 312 is not etched.

The spacers 312 are then removed using a suitable etching process, leaving the desired fin structures 104 and 106 and inter-fin strip 202 (FIG. 10). Subsequently, a gate oxide layer and gate electrode are formed orthogonal to fins 104 and 106, resulting in a structure as shown in FIG. 2. For the sake of brevity, the formation of gate dielectric and gate electrode are not shown, as they are conventional FinFET fabrication steps known in the art.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

What is claimed is:

1. A method for fabricating a FinFET structure, the method comprising:
providing a semiconductor substrate having a top surface;
patterning the semiconductor substrate to form a nonplanar semiconductor structure comprising a first fin, a second fin substantially parallel to the first fin, and an inter-fin semiconductor strip coupled therebetween, wherein the first fin, the second fin, and the inter-fin semiconductor strip each extend from a drain region to a source region such that the first and second fins extend a first distance from the top surface of the substrate, and the inter-fin semiconductor strip extends a second distance from the top surface of the substrate, wherein the first distance is approximately five times the second distance;
forming a gate dielectric layer on the first and second fins and the inter-fin semiconductor strip in a gate region substantially orthogonal to the first and second fins and between the drain and source region; and
forming a gate electrode layer on the gate dielectric layer.

2. The method of claim 1, wherein the step of providing a semiconductor substrate comprises providing a silicon-on-insulator substrate.

3. The method of claim 2, wherein the step of providing a silicon-on-insulator substrate comprises providing a silicon layer on a buried oxide layer.

4. The method of claim 1, wherein the patterning step includes patterning the semiconductor substrate such that the inter-fin semiconductor strip has a first thickness and the first fin has a second thickness that is greater than the first thickness by approximately a factor of 2 to 5.

5. The method of claim 1, further including:
forming a plurality of fins parallel to the first fin, such that a total of N fins are fabricated; and
forming a plurality of inter-fin semiconductor strips between each pair of fins n and n+1 for n=1 to N−1, inclusive.

6. The method of claim 1, wherein the patterning step includes:
forming a dielectric layer on the semiconductor substrate;
patterning the dielectric layer to form a dielectric strip;
etching the silicon substrate to remove a portion of the semiconductor substrate on first and second sides of the dielectric strip such that the semiconductor substrate has a first thickness below the dielectric strip and a second thickness on the first and second sides of the dielectric strip, wherein the first thickness is greater than the second thickness;
forming a first sidewall dielectric structure on the first side of the dielectric strip, and forming a second sidewall dielectric structure on the second side of the dielectric strip;
etching the semiconductor to form the first fin under the first sidewall dielectric structure, the second fin under the second sidewall dielectric structure, and the inter-fin semiconductor strip therebetween; and
removing the first and second sidewall dielectric structures.

7. The method of claim 6, wherein the step of providing the silicon substrate includes providing a silicon-on-insulator substrate comprising a silicon layer over a buried oxide layer, and wherein the step of etching the silicon substrate includes etching the silicon substrate until the buried oxide layer is exposed except between the first and second sidewall dielectric structures.

8. A method of forming a FinFET structure having a plurality of fins extending between a drain region and a source region, the method including: forming inter-fin strips between adjacent pairs of the plurality of fins, wherein the inter-fin strips and the plurality of fins are contiguous and comprise the same material, and wherein the plurality of fins extend a first distance from the top surface of a substrate, the inter-fin strips extends a second distance from the top surface of the substrate, and the first distance is approximately five times the second distance.

9. The method of claim 8, wherein the step of forming the inter-fin strips includes forming first and second sidewall structures on a semiconductor layer and selectively etching the semiconductor layer such that it has a first thickness between the first and second sidewall structures and a second thickness, less than the first thickness, external to the sidewall structures.

10. The method of claim 9, further including subsequently etching the semiconductor layer such that the inter-fin strips are formed from the semiconductor layer between the first and second sidewall structures.

11. The method of claim 9, wherein the first thickness is approximately 5-20 nm greater than the second thickness.

12. The method of claim 8, wherein forming the inter-fin strips includes forming an interfin strip comprising silicon.

13. The method of claim 12, wherein forming the inter-fin strips includes selectively etching a silicon-on-insulator substrate.

14. The method of claim 8, further including forming a gate dielectric layer on the fins and the inter-fin semiconductor strip in a gate region substantially orthogonal to the fins and between the drain and source region; and
forming a gate electrode layer on the gate dielectric layer.

15. A nonplanar field effect transistor structure comprising:
a first semiconductor fin extending from a drain region to a source region;
a second semiconductor fin extending from the drain region to the source region, wherein the second semiconductor fin is substantially parallel to the first semiconductor fin;
an inter-fin semiconductor strip between, and in electrical communication with, the first and second fins;
a gate dielectric layer on the first and second fins and the inter-fin semiconductor strip in a gate region substantially orthogonal to the first and second fins and between the drain and source regions; and
a gate electrode formed on the gate dielectric layer.

16. The structure of claim 15, wherein the first semiconductor fin, the second semiconductor fin, and the inter-fin semiconductor strip each comprise silicon.

17. The structure of claim 16, wherein first semiconductor fin, the second semiconductor fin, and the inter-fin semiconductor strip each comprise silicon formed over a buried oxide layer.

18. The structure of claim 15, wherein the inter-fin semiconductor strip has a thickness of between approximately 5 and 20 nm.
